(19) United States
(12) Patent Application Publication
(10) Pub. No.: US 2024/0304475 A1
(43) Pub. Date: Sep. 12, 2024

(54) BONDING APPARATUS, BONDING SYSTEM, AND BONDING METHOD

(71) Applicant: Tokyo Electron Limited, Tokyo (JP)

(72) Inventors: Kenji Sugakawa, Koshi City, Kumamoto (JP); Tetsuya Maki, Koshi City, Kumamoto (JP)

(21) Appl. No.: 18/598,273

(22) Filed: Mar. 7, 2024

(30) Foreign Application Priority Data
Mar. 8, 2023 (JP) 2023-035417

(51) Int. Cl. H01L 21/67; H01J 37/32

(52) U.S. Cl. CPC H01L 21/67144; H01J 37/32073; H01L 21/67017; H01L 21/67092

(57) ABSTRACT

A bonding apparatus includes a first holder, a second holder, a striker and an ionizer. The first holder is configured to attract and hold a first substrate from above. The second holder is disposed below the first holder and is configured to attract and hold a second substrate from below. The striker is configured to press a central portion of the first substrate into contact with the second substrate. The ionizer is disposed above the second holder.

### CROSS-REFERENCE TO RELATED APPLICATION

This application claims the benefit of Japanese Patent Application No. 2023-035417 filed on Mar. 8, 2023, the entire disclosure of which is incorporated herein by reference.

### TECHNICAL FIELD

The various aspects and embodiments described herein pertain generally to a bonding apparatus, a bonding system, and a bonding method.

### BACKGROUND

Conventionally, there is known a bonding apparatus for bonding substrates such as semiconductor wafers (see, for example, Patent Document 1).
Patent Document 1: Japanese Patent Laid-open Publication No. 2018-147944

### SUMMARY

In one exemplary embodiment, a bonding apparatus includes a first holder, a second holder, a striker and an ionizer. The first holder is configured to attract and hold a first substrate from above. The second holder is disposed below the first holder and is configured to attract and hold a second substrate from below. The striker is configured to press a central portion of the first substrate into contact with the second substrate. The ionizer is disposed above the second holder.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic diagram illustrating a configuration of a bonding system according to a first exemplary embodiment;

FIG. 2 is a schematic diagram illustrating a state of a first substrate and a second substrate before they are bonded according to the first exemplary embodiment;

FIG. 3 is a schematic plan view of a bonding apparatus according to the first exemplary embodiment;

FIG. 4 is a schematic side view of the bonding apparatus according to the first exemplary embodiment;

FIG. 5 is a schematic side view of a first holder and a second holder according to the first exemplary embodiment;

FIG. 6A is a schematic diagram for describing charge neutralization by an ionizer;

FIG. 6B is a schematic diagram for describing the charge neutralization by the ionizer;

FIG. 7A is a schematic diagram for describing the charge neutralization by the ionizer;

FIG. 7B is a schematic diagram for describing the charge neutralization by the ionizer;

FIG. 8 is a flowchart illustrating a sequence of a processing performed by the bonding system according to the first exemplary embodiment;

FIG. 9 is a schematic diagram illustrating a configuration example of a second holder of a bonding apparatus according to a second exemplary embodiment; and

FIG. 10 is a flowchart illustrating a sequence of a processing performed by a bonding system according to the second exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, embodiments for a bonding apparatus, a bonding system, and a bonding method according to the present disclosure (hereinafter, referred to as “exemplary embodiments”) will be described in detail with reference to the accompanying drawings. Further, it should be noted that the bonding apparatus, the bonding system and the bonding method according to the present disclosure are not limited by the exemplary embodiments. Further, unless processing contents are contradictory, the various exemplary embodiments can be appropriately combined. Furthermore, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some tolerable errors in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “0 direction.”

In recent years, semiconductor devices are getting highly integrated. If a multiple number of highly integrated semiconductor devices are placed on a horizontal plane and theses semiconductor devices are connected by wiring to be produced as a product, there is a concern that the length of the wiring may be increased, resulting in an increase of resistance of the wiring and an increase of a wiring delay.

In view of this, it has been proposed to use a three-dimensional integration technique of stacking semiconductor devices three-dimensionally. In this three-dimensional integration technique, two sheets of semiconductor wafers (hereinafter, referred to as “substrates”) are bonded by using a bonding system described in Patent Document 1, for example.

In a bonding apparatus of this bonding system, one substrate (hereinafter, referred to “first substrate”) and the other substrate (hereinafter, referred to as “second substrate”) are bonded together in the state that the first substrate is held by using a first holder and the second substrate is held by using a second holder that is disposed below the first holder.

In the bonding apparatus according to the prior art, however, there is a risk that a bonding defect may occur when the first substrate and the second substrate are bonded. That is, if the holder or the substrate, for example, is relatively highly charged, an electric discharge occurs between the first substrate and the second substrate when they are bonded, and this electric discharge causes a bonding defect. Specifically, due to the electric discharge, a void (air bubble) is created between the first substrate and the second substrate, resulting in poor bonding between the substrates.

In view of this, the bonding apparatus according to the present exemplary embodiment adopts a configuration capable of suppressing a bonding defect when substrates are bonded.

### First Exemplary Embodiment

### <Configuration of Bonding System>

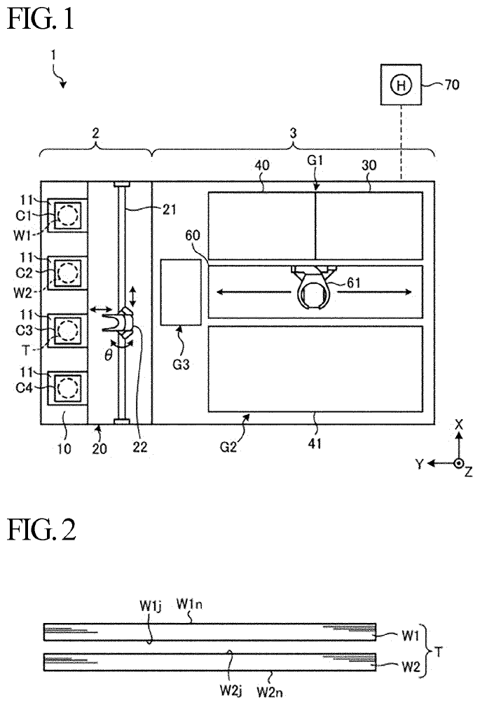

First, a configuration of a boding system according to a first exemplary embodiment will be described with reference to FIG. 1 and FIG. 2. FIG. 1 is a schematic diagram illustrating the configuration of the bonding system according to the first exemplary embodiment. FIG. 2 is a schematic diagram illustrating a state of a first substrate and a second substrate before they are bonded according to the first exemplary embodiment.

A bonding system 1 shown in FIG. 1 is configured to form a combined substrate T by bonding a first substrate W1 and a second substrate W2 (see FIG. 2).

The first substrate W1 and the second substrate W2 are single crystalline silicon wafers, and a multiple number of electronic circuits are formed on their plate surfaces. The first substrate W1 and the second substrate W2 have the substantially same diameter. Alternatively, either one of the first substrate W1 and the second substrate W2 may be a substrate on which no electronic circuit is formed.

In the following description, as shown in FIG. 2, among plate surfaces of the first substrate W1, a plate surface to be bonded to the second substrate W2 will be referred to as “bonding surface W1j”, and a plate surface opposite to the bonding surface W1j will be referred to as “non-bonding surface W1n”. Further, among plate surfaces of the second substrate W2, a plate surface to be bonded to the first substrate W1 will be referred to as “bonding surface W2j”, and a plate surface opposite to the bonding surface W2j will be referred to as “non-bonding surface W2n”.

As depicted in FIG. 1, the bonding system 1 includes a carry-in/out station 2 and a processing station 3. The carry-in/out station 2 is disposed on the positive Y-axis side of the processing station 3, and is connected as a single body with the processing station 3.

The carry-in/out station 2 includes a placing table 10 and a transfer section 20. The placing table 10 is equipped with a multiple number of placing plates 11. Respectively provided on the placing plates 11 are cassettes C1 to C4 each of which accommodates therein a plurality of (e.g., 25 sheets of) substrates horizontally. The cassette C1 accommodates therein a plurality of first substrates W1; the cassette C2, a plurality of second substrates W2; and the cassette C3, a plurality of combined substrates T. The cassette C4 is a cassette for collecting, for example, a defective substrate. Further, the number of the cassettes C1 to C4 placed on the placing plates 11 is not limited to the shown example.

The transfer section 20 is provided adjacent to the negative Y-axis side of the placing table 10. Provided in the transfer section 20 are a transfer path 21 extending in the X-axis direction and a transfer device 22 configured to be movable along the transfer path 21. The transfer device 22 is configured to be movable in the X-axis direction as well as in the Y-axis direction and pivotable around the Z-axis. The transfer device 22 transfers the first substrates W1, the second substrates W2, and the combined substrates T between the cassettes C1 to C4 placed on the placing plates 11 and a third processing block G3 of the processing station 3 to be described later.

The processing station 3 is provided with, for example, three processing blocks G1, G2 and G3. The first processing block G1 is disposed on the rear side (positive X-axis side of FIG. 1) of the processing station 3. Further, the second processing block G2 is provided on the front side (negative X-axis side of FIG. 1) of the processing station 3, and the third processing block G3 is disposed on the carry-in/out station 2 side (positive Y-axis side of FIG. 1) of the processing station 3.

Disposed in the first processing block G1 is a surface modifying apparatus 30 configured to modify the bonding surface W1j of the first substrate W1 and the bonding surface W2j of the second substrate W2. The surface modifying apparatus 30 cuts a SiO₂ bond on the bonding surfaces W1j and W2j of the first and second substrates W1 and W2 into a single bond of SiO, thus allowing the bonding surfaces W1j and W2j to be modified so that they are easily hydrophilized afterwards.

Specifically, in the surface modifying apparatus 30, an oxygen gas or a nitrogen gas as a processing gas is excited into plasma under, for example, a decompressed atmosphere to be ionized. As these oxygen ions or nitrogen ions are radiated to the bonding surfaces W1j and W2j of the first and second substrates W1 and W2, the bonding surfaces W1j and W2j are modified by being plasma-processed.

Further, in the first processing block G1, a surface hydrophilizing apparatus 40 is disposed. The surface hydrophilizing apparatus 40 is configured to hydrophilize and clean the bonding surfaces W1j and W2j of the first and second substrates W1 and W2 with, for example, pure water. To elaborate, the surface hydrophilizing apparatus 40 supplies the pure water onto the first substrate W1 or the second substrate W2 while rotating the first substrate W1 or the second substrate W2 held by, for example, a spin chuck. Accordingly, the pure water supplied onto the first substrate W1 or the second substrate W2 is diffused on the bonding surface W1j of the first substrate W1 or the bonding surface W2j of the second substrate W2, so that the bonding surfaces W1j and W2j are hydrophilized.

Here, although the surface modifying apparatus 30 and the surface hydrophilizing apparatus 40 are arranged side by side, the surface hydrophilizing apparatus 40 may be stacked on top of or under the surface modifying apparatus 30.

In the second processing block G2, a bonding apparatus 41 is disposed. The boning apparatus 41 is configured to bond the hydrophilized first and second substrates W1 and W2 by an intermolecular force. A specific configuration of the bonding apparatus 41 will be described later.

A transfer section 60 is formed in a region surrounded by the first processing block G1, the second processing block G2, and the third processing block G3. A transfer device 61 is disposed in the transfer section 60. The transfer device 61 has a transfer arm configured to be movable in a vertical direction and a horizontal direction and pivotable around a vertical axis, for example. This transfer device 61 is moved within the transfer section 60 and transfers the first substrate W1, the second substrate W2 and the combined substrate T to preset apparatuses within the first processing block G1, the second processing block G2, and the third processing block G3 which are adjacent to the transfer section 60.

Furthermore, the bonding system 1 is equipped with a control device 70. The control device 70 controls an operation of the bonding system 1. This control device 70 may be implemented by, for example, a computer, and includes a controller and a storage that are not illustrated here. The controller includes a microcomputer having a CPU (Central Processing Unit), a ROM (Read Only Memory), a RAM (Random Access Memory), an input/output port, and so forth as well as various kinds of circuits. The CPU of the microcomputer implements a control to be described later by reading out and executing a program stored in the ROM. Further, the storage may be implemented by, for example, a semiconductor memory device such as a RAM or a flash memory, or a storage device such as a hard disk or an optical disk.

Further, the program may be recorded on a computer-readable recording medium and installed from the recording medium to the storage of the control device 70. The computer-readable recording medium may be, by way of non-limiting example, a hard disk HD, a flexible disk FD, a compact disk CD, a magnetic optical disk MO, a memory card, or the like.

### <Configuration of Bonding Apparatus>

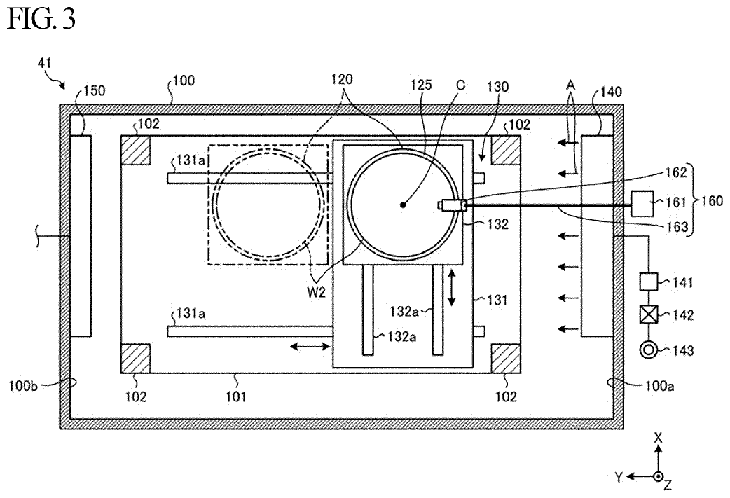

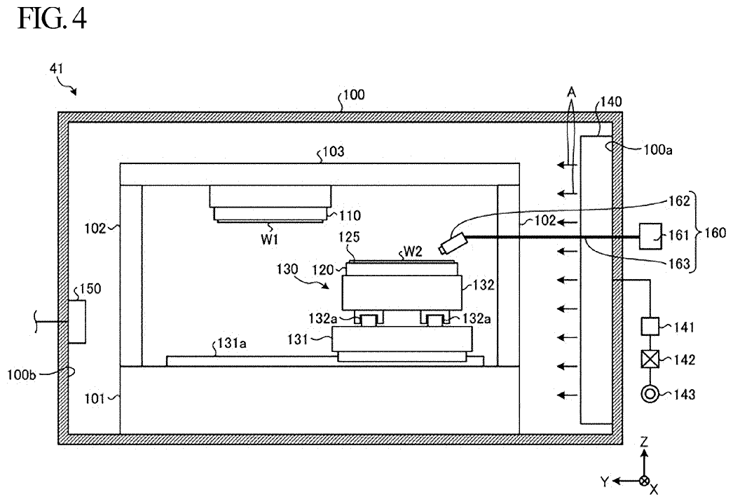

Here, the configuration of the bonding apparatus 41 will be explained with reference to FIG. 3 and FIG. 4. FIG. 3 is a schematic plan view of the bonding apparatus 41 according to the first exemplary embodiment. FIG. 4 is a schematic side view of the bonding apparatus 41 according to the first exemplary embodiment.

As depicted in FIG. 3 and FIG. 4, the bonding apparatus 41 according to the present exemplary embodiment includes a housing 100, a first holder 110, a second holder 120, a moving device 130, a gas supply 140, an exhaust device 150, and an ionizer 160.

The housing 100 is, for example, a box body having a rectangular shape when viewed from the top, and it accommodates therein the first holder 110, the second holder 120, the moving device 130, the gas supply 140, the exhaust device 150, and the ionizer 160 (precisely, a part of the ionizer 160).

Further, a placing table 101, a plurality of supporting columns 102 standing upright on a top surface of the placing table 101, and a ceiling member 103 supported by the plurality of supporting columns 102 are disposed within the housing 100.

The first holder 110 attracts and holds a top surface (non-bonding surface W1n) of the first substrate W1 from above. The first holder 110 is supported by the ceiling member 103 (see FIG. 4). The second holder 120 is provided below the first holder 110, and attracts and holds a bottom surface (non-bonding surface W2n) of the second substrate W2 from below.

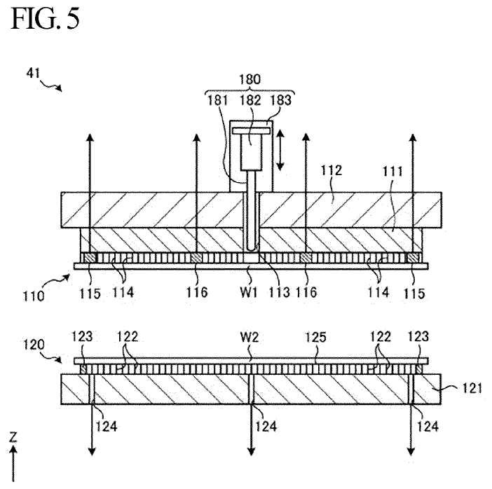

Here, a configuration example of the first holder 110 and the second holder 120 will be described with reference to FIG. 5. FIG. 5 is a schematic side view of the first holder 110 and the second holder 120 according to the first exemplary embodiment.

As depicted in FIG. 5, the first holder 110 has a main body 111. The main body 111 is supported by a supporting member 112. A through hole 113 is formed through the supporting member 112 and the main body 111 in a vertical direction. The position of the through hole 113 corresponds to a central portion of the first substrate W1 attracted to and held by the first holder 110. A push pin 181 of a striker 180 to be described later is inserted through this through hole 113.

The striker 180 is disposed on a top surface of the supporting member 112 and is equipped with the push pin 181, an actuator device 182, and a linearly moving mechanism 183. The push pin 181 is a columnar member extending along the vertical direction, and is supported by the actuator device 182.

The actuator device 182 is configurated to generate a regular pressure in a certain direction (here, a vertically downward direction) by air supplied from, for example, an electro-pneumatic regulator (not shown). By the air supplied from the electro-pneumatic regulator, the actuator device 182 is capable of controlling a press load applied to the central portion of the first substrate W1 when it is brought into contact with the central portion of the first substrate W1. Further, a leading end of the push pin 181 is movable up and down in the vertical direction through the through hole 113 by the air from the electro-pneumatic regulator.

The actuator device 182 is supported by the linearly moving mechanism 183. The linearly moving mechanism 183 moves the actuator device 182 along the vertical direction by a driving device having therein a motor, for example.

The striker 180 controls a movement of the actuator device 182 by the linearly moving mechanism 183, and controls the press load on the first substrate W1 from the push pin 181 by the actuator device 182. With this configuration, the striker 180 presses the central portion of the first substrate W1 attracted to and held by the first holder 110 into contact with the second substrate W2.

A plurality of pins 114 is provided on a bottom surface of the main body 111, and these pins 114 come into contact with the top surface (non-bonding surface) of the first substrate W1. Each pin 114 has a diameter of, e.g., 0.1 mm to 1 mm and a height of, e.g., several tens of micrometers (μm) to several hundreds of micrometers (μm). The plurality of pins 114 are uniformly arranged at a distance of, e.g., 2 mm therebetween.

The first holder 110 is equipped with a plurality of attraction portions for attracting the first substrate W1 in a part of the regions where the plurality of pins 114 are provided. Specifically, a plurality of outer attraction portions 115 and a plurality of inner attraction portions 116 for attracting the first substrate W1 by evacuation are provided in a bottom surface of the main body 111 of the first holder 110. Each of the plurality of outer attraction portions 115 and the plurality of inner attraction portions 116 has an arc-shaped attraction region when viewed from the top. The outer attraction portions 115 and the inner attraction portions 116 have the same height as the pins 114.

The plurality of outer attraction portions 115 are provided at a peripheral portion of the main body 111. The plurality of outer attraction portions 115 are connected to a non-illustrated suction device such as a vacuum pump to attract and hold a peripheral portion of the first substrate W1 by evacuation.

The inner attraction portions 116 are arranged along a circumferential direction of the main body 111 at an inner side than the plurality outer attraction portions 115 in a diametrical direction of the main body 111. The plurality of inner attraction portions 116 are connected to a non-illustrated suction device such as a vacuum pump to attract a region between the peripheral portion and the central portion of the first substrate W1 by evacuation.

The second holder 120 will be explained. The second holder 120 has a main body 121 having a diameter equal to or larger than the diameter of the second substrate W2. Here, the second holder 120 having a diameter larger than that of the second substrate W2 is shown. A top surface of the main body 121 is a facing surface facing the bottom surface (non-bonding surface W2n) of the second substrate W2.

A plurality of pins 122 is provided on the top surface of the main body 121, and these pins 122 come into contact with the bottom surface (non-bonding surface W2n) of the second substrate W2. Each pin 122 has a diameter of, e.g., 0.1 mm to 1 mm and a height of, e.g., several tens of micrometers (μm) to several hundreds of micrometers (μm). These pins 122 are uniformly arranged at a distance of, e.g., 2 mm therebetween.

Moreover, a lower rib 123 is provided in an annular shape on the top surface of the main body 121 to be located outside the plurality of pins 122. The lower rib 123 is formed in the annular shape and supports the peripheral portion of the second substrate W2 over the entire circumference thereof.

Further, the main body 121 has a plurality of lower suction openings 124. The plurality of lower suction openings 124 are provided in an attraction region surrounded by the lower rib 123. These lower suction openings 124 are connected to a non-illustrated suction device such as a vacuum pump via a non-illustrated suction line.

The second holder 120 decompresses the attraction region surrounded by the lower rib 123 by evacuating the attraction region through the plurality of lower suction openings 124. Accordingly, the second substrate W2 disposed in the attraction region is attracted to and held by the second holder 120.

Since the lower rib 123 supports the peripheral portion of the bottom surface of the second substrate W2 over the entire circumference thereof, the second substrate W2 is properly suctioned up to the peripheral portion thereof. Accordingly, the entire surface of the second substrate W2 can be attracted and held. Further, since the bottom surface of the second substrate W2 is supported by the plurality of pins 122, the second substrate W2 may be easily separated from the second holder 120 when the suctioning of the second substrate W2 is released.

This bonding apparatus 41 attracts and holds the first substrate W1 with the first holder 110, and attracts and holds the second substrate W2 with the second holder 120. Then, the bonding apparatus 41 releases the attracting and holding of the first substrate W1 by the inner attraction portions 116, and lowers the push pin 181 of the striker 180 to press the central portion of the first substrate W1. As a result, the combined substrate T in which the first substrate W1 and the second substrate W2 are bonded to each other is obtained. The combined substrate T is carried out from the bonding apparatus 41 by the transfer device 61.

Further, the first and second holders 110 and 120 are formed of an insulating (non-conductive) member such as alumina ceramics or silicon nitride, but are not limited thereto.

In addition, the second holder 120 is equipped with an elevating device 170 configured to perform a descending operation to receive the second substrate W2 carried into the bonding apparatus 41 and lower the received second substrate W2 to a holding surface (top surface) 125 and an ascending operation to raise the combined substrate T from the holding surface 125 up to a carry-out position, as will be described later.

Referring back to FIG. 3 and FIG. 4, a configuration of the moving device 130 will be described. The moving device 130 is configured to move the second holder 120 in the horizontal direction. Specifically, the moving device 130 includes a first moving device 131 configured to move the second holder 120 along the Y-axis direction, and a second moving device 132 configured to move the second holder 120 along the X-axis direction.

The first moving device 131 is mounted to a pair of first rails 131a extending in the Y-axis direction, and is configured to be movable along the pair of first rails 131a. The pair of first rails 131a are provided on the top surface of the placing table 101.

The second moving device 132 is mounted to a pair of second rails 132a extending in the X-axis direction, and is configured to be movable along the pair of second rails 132a. The pair of second rails 132a are provided on a top surface of the first moving device 131.

The second holder 120 is mounted to the second moving device 132, and is moved as one body with the second moving device 132. Moreover, as stated above, the second moving device 132 is mounted to the first moving device 131 with the pair of second rails 132a therebetween. With this configuration, the moving device 130 is capable of moving the second holder 120 along the Y-axis direction by moving the first moving device 131, and capable of moving the second holder 120 in the X-axis direction by moving the second moving device 132.

Moreover, the second moving device 132 is configured to move the second holder 120 in the vertical direction and, also, rotate it around a vertical axis.

In this way, by moving the second holder 120 in the X-axis, the Y-axis and the θ directions, the moving device 130 performs position alignment between the first substrate W1 held by the first holder 110 and the second substrate W2 held by the second holder 120 in the horizontal direction. Further, by moving the second holder 120 in the Z-axis direction, the moving device 130 performs position alignment between the first substrate W1 held by the first holder 110 and the second substrate W2 held by the second holder 120 in the vertical direction.

Further, the moving device 130 only needs to be able to move the first holder 110 and the second holder 120 relative to each other in the X-axis, the Y-axis and the θ directions. By way of example, the moving device 130 may move the first holder 110 in the X-axis direction, the Y-axis direction, and the θ direction. Alternatively, the moving device 130 may move the second holder 120 in the X-axis direction and the Y-axis direction while moving the first holder 110 in the θ direction.

In addition, the moving device 130 also moves the second holder 120 when the second substrate W2 is carried into the bonding apparatus 41 and when the combined substrate T is carried out from the bonding apparatus 41. Specifically, the moving device 130 moves the first and second moving devices 131 and 132 to move the second holder 120 between a carry-in/out position where the carry-in of the second substrate W2 and the carry-out of the combined substrate T are performed and a facing position where the second holder 120 faces the first holder 110. Moreover, in the example of FIG. 3, the second holder 120 located at the carry-in/out position is indicated by a solid line, and the second holder 120 located at the facing position is indicated by a dashed double-dotted line. Furthermore, as the second substrate W2 held by the second holder 120 placed at the facing position is bonded to the first substrate W1 held by the first holder 110, the facing position may also be referred to as a bonding position.

The gas supply 140 is a fan filter unit (FFU), and is configured to supply a cleaned gas into the housing 100. The gas is, for example, dry air or an inert gas such as a nitrogen gas or an argon gas.

The gas supply 140 is connected to a gas source 143 via a temperature regulator 141 and a valve 142. When the valve 142 is opened, the gas supply 140 discharges the gas adjusted to a preset temperature by the temperature regulator 141 after being supplied from the gas source 143 into the housing 100.

In the example of FIG. 3 and FIG. 4, the gas supply 140 is provided on a side surface 100a orthogonal to the Y-axis direction among a plurality of side surfaces of the housing 100. The gas supply 140 discharges the gas along the Y-axis direction (specifically, positive Y-axis direction) (as indicated by arrows A).

The exhaust device 150 is provided on, among the plurality of side surfaces of the housing 100, a side surface 100b opposite to the side surface 100a to which the gas supply 140 is mounted. The exhaust device 150 is connected to a non-illustrated suction device such as a vacuum pump, and evacuates the housing 100 by using a suction force of the suction device.

As described above, in the bonding apparatus 41 according to the first exemplary embodiment, a side flow is formed within the housing 100 by the gas supply 140 provided on one side surface 100a of the housing 100 and the exhaust device 150 provided on another side surface 100b opposite to the side surface 100a.

The ionizer 160 is a charge neutralizing device configured to neutralize electric charges of the second substrate W2 and the second holder 120 that are charged. Although the ionizer 160 is configured to neutralize the electric charges of both the second substrate W2 and the second holder 120 in the following example, the present exemplary embodiment is not limited thereto, and the ionizer 160 may be configured to neutralize at least one of the second substrate W2 or the second holder 120.

Here, charging of the second substrate W2 and the second holder 120 will be described. For example, the second substrate W2 may be charged in a processing performed before it is carried into the bonding apparatus 41, and may be carried into the bonding apparatus 41 in the charged state. When the charged second substrate W2 is carried in and held on the second holder 120, the second holder 120 is also charged. Further, the second holder 120 holds the combined substrate T after being subjected to the bonding processing, and the combined substrate T held by the second holder 120 is carried out from the bonding apparatus 41. During this carrying-out operation, if the combined substrate T is separated from the second holder 120, the second holder 120 is charged due to this separation.

If the second substrate W2 and the second holder 120 are charged as described above, a difference in charged amount between the first substrate W1 and the second substrate W2 may increase when the first substrate W1 and the second substrate W2 are bonded, which may result in occurrence of an electric discharge. When such an electric discharge takes place, a void is created between the first substrate W1 and the second substrate W2 (for example, near the central portions of the first and second substrates W1 and W2) due to this electric discharge, which may result in defective bonding between the substrates. For this reason, in the present exemplary embodiment, the ionizer 160 is used to neutralize the electric charges of the second substrate W2 and the second holder 120 that are charged.

The ionizer 160 according to the present exemplary embodiment is disposed above the second holder 120. To elaborate, the ionizer 160 includes a power supply 161, a head 162, and a cable 163. Further, the ionizer 160 is a separate type ionizer in which the power supply 161 is separated from the head 162.

The power supply 161 is disposed outside the housing 100. The power supply 161 is connected to the head 162 via the cable 163. The power supply 161 generates a high-level voltage. The power supply 161 supplies the generated high-level voltage to the head 162 via the cable 163.

The head 162 is disposed inside the housing 100. The head 162 is provided with a non-illustrated discharge electrode. The high-level voltage from the power supply 161 is applied to the discharge electrode of the head 162, causing a corona discharge. As a result, the head 162 emits (radiates) positive and negative ions.

In the above-described example, the ionizer 160 is the corona discharge type ionizer. However, the exemplary embodiment is not limited thereto, and other types of ionizers, such as, but not limited to, a soft X-ray type or an ultraviolet type, may be used.

In the ionizer 160 according to the present exemplary embodiment, the head 162 is disposed to be positioned above the second holder 120. In detail, in the ionizer 160, the head 162 is disposed to be located above the second holder 120 which is placed at the carry-in/out position. Specifically, the head 162 is disposed at a position spaced apart from the holding surface 125 of the second holder 120 located at the carry-in/out position by a preset distance. This preset distance is set to tens of millimeters or hundreds of millimeters, but is not limited thereto, and may be set to any required value.

The head 162 disposed at the above-described position emits positive and negative ions toward the second substrate W2 and the second holder 120, thereby neutralizing the electric charges of the second substrate W2 and the second holder 120 that are charged.

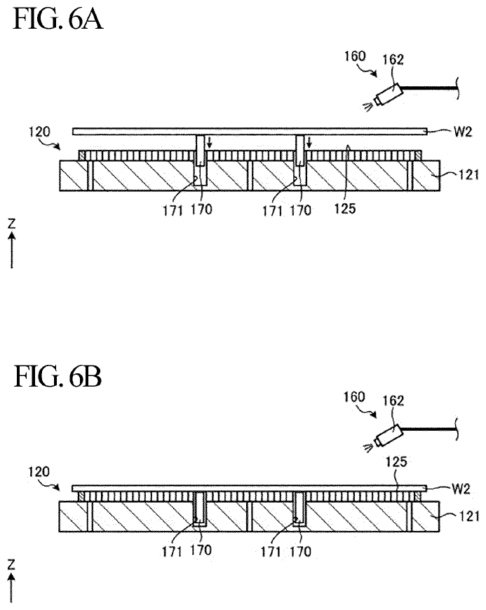

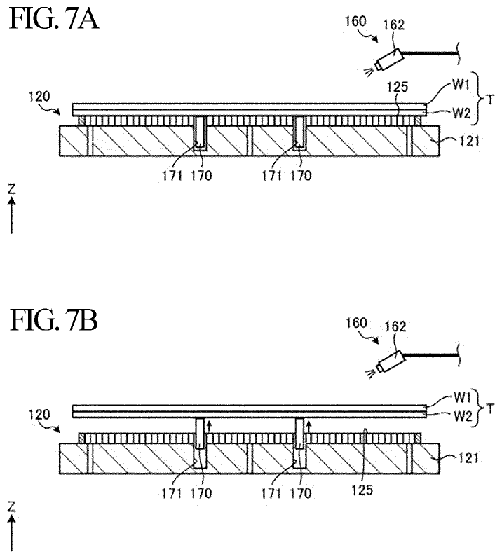

Here, the charge neutralization by the ionizer 160 will be described with reference to FIG. 6A to FIG. 7B. FIG. 6A to FIG. 7B are schematic diagrams for explaining the charge neutralization by the ionizer 160. FIG. 6A and FIG. 6B are diagrams for describing neutralization of the second substrate W2 carried into the bonding apparatus 41 in the charged state and neutralization of the second holder 120 holding this second substrate W2. FIG. 7A and FIG. 7B are diagrams for describing neutralization of the second holder 120 having been charged as a result of the combined substrate T being separated from the second holder 120 when the combined substrate T is carried out from the bonding apparatus 41.

As shown in FIG. 6A, the second holder 120 is provided with the aforementioned elevating device 170. The elevating device 170 includes a plurality of (for example, three, and only two of them are shown in FIG. 6A, etc.) pins. The elevating device 170 is configured to be inserted into an insertion through hole 171 formed in the main body 121 to be movable up and down in a vertical direction (Z-axis direction).

The elevating device 170 receives the carried second substrate W2 when its leading end is protruded from the holding surface 125 (see FIG. 6A). Thereafter, as illustrated in FIG. 6B, the elevating device 170 lowers its leading end to a position below the holding surface 125 to lower the second substrate W2 to the holding surface 125, thus allowing the second substrate W2 to be held by the second holder 120.

Since the ionizer 160 is disposed above the second holder 120, even when the second substrate W2 is carried-in in the charged state, it is capable of emitting the ions to the second substrate W2 to neutralize it. Also, since the second holder 120 holds the neutralized second substrate W2, charging of the second holder 120 can be suppressed. Additionally, the ionizer 160 is also capable of discharging the ions to the second holder 120 holding the second substrate W2, thereby neutralizing the second holder 120.

Moreover, as depicted in FIG. 7A, the combined substrate T after being subjected to the bonding processing is held on the holding surface 125 of the second holder 120. Afterwards, as depicted in FIG. 7B, the leading end of the elevating device 170 is protruded from the holding surface 125 to separate the combined substrate T from the holding surface 125 and raise it to the carry-out position. Then, the combined substrate T is carried out from the bonding apparatus 41.

Since the ionizer 160 is disposed above the second holder 120, even when the second holder 120 is charged due to the separation of the combined substrate T, it is capable of emitting the ions toward the second holder 120 to thereby neutralize the second holder 120.

In this way, in the present exemplary embodiment, the ionizer 160 disposed above the second holder is configured to neutralize the electric charges of the second substrate W2 and the second holder 120. Accordingly, when the first substrate W1 and the second substrate W2 are bonded in the current processing or the next processing, the difference in charged amount between the first substrate W1 and the second substrate W2 may decrease, and the occurrence of the electric discharge may be suppressed. Therefore, the formation of the void between the first substrate W1 and the second substrate W2, which is caused by the electric discharge, can be suppressed, and, as a result, the bonding defect when bonding the substrates to each other can be suppressed.

Reference is made back to FIG. 3 and FIG. 4. The power supply 161 of the ionizer 160 generates heat when it generates the high-level voltage. In the ionizer 160 according to the present exemplary embodiment, the power supply 161 that generates the heat is disposed outside the housing 100, as stated above. In detail, the power supply 161 is disposed in an external space different from the internal space of the housing 100. Meanwhile, the head 162 that emits the ions is disposed inside the housing 100.

With this configuration, the ionizer 160 is capable of neutralizing the electric charges of the second holder 120 and the like within the housing 100 with the ions from the head 162, and an influence of the heat generated in the power supply 161 on the internal space of the temperature-regulated housing 100 can be reduced.

In addition, as shown in FIG. 3, the ionizer 160 (more precisely, the head 162) is disposed on the upstream side of the gas flow with respect to a center position C of the second holder 120. In detail, the ionizer 160 (head 162) is disposed at a position above the second holder 120 and shifted from the center position C of the second holder 120 to the upstream side of the gas flow.

With this configuration, the ionizer 160 can cause the emitted ions to reach a wide range of the second substrate W2 or second holder 120 along the gas flow, so that the electric charges of the second substrate W2 and the second holder 120 can be neutralized efficiently.

In addition, although not illustrated here, the bonding apparatus 41 is further equipped with a transition, a position adjusting mechanism, an inverting mechanism, and so forth. In the transition, the first substrate W1, the second substrate W2 and the combined substrate T are temporarily disposed. The position adjusting mechanism adjusts the directions of the first substrate W1 and the second substrate W2 in the horizontal direction. The inverting mechanism inverts the front and rear surfaces of the first substrate W1.

### <Specific Operation of Bonding System>

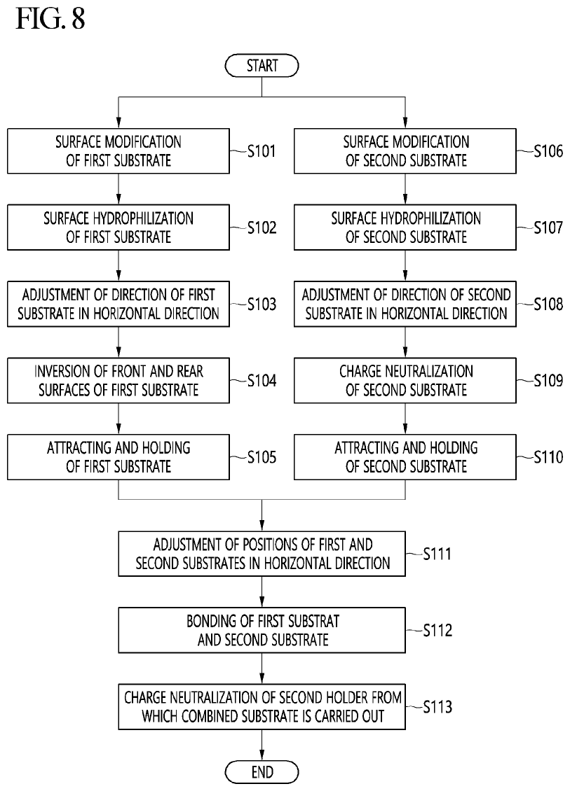

Now, a specific operation of the bonding system 1 according to the first exemplary embodiment will be discussed with reference to FIG. 8. FIG. 8 is a flowchart illustrating a sequence of a processing performed by the bonding system 1 according to the first exemplary embodiment. The various processes shown in FIG. 8 are performed under the control of the control device 70.

First, the cassette C1 accommodating the plurality of first substrates W1, the cassette C2 accommodating the plurality of second substrates W2, and the empty cassette C3 are placed on the preset placing plates 11 of the carry-in/out station 2. Then, the first substrate W1 is taken out from the cassette C1 by the transfer device 22, and transferred into the transition disposed within the third processing block G3.

Then, the first substrate W1 is transferred to the surface modifying apparatus 30 of the first processing block G1 by the transfer device 61. In the surface modifying apparatus 30, an oxygen gas as a processing gas is excited into plasma to be ionized under a preset decompressed atmosphere. Oxygen ions are radiated to the bonding surface of the first substrate W1, so that the bonding surface is plasma-processed. As a result, the bonding surface of the first substrate W1 is modified (process S101).

Subsequently, the first substrate W1 is transferred to the surface hydrophilizing apparatus 40 of the first processing block G1 by the transfer device 61. In the surface hydrophilizing apparatus 40, pure water is supplied onto the first substrate W1 while rotating the first substrate W1 held by the spin chuck. As a result, the bonding surface of the first substrate W1 is hydrophilized. Further, the bonding surface of the first substrate W1 is cleaned by this pure water (process S102).

Next, the first substrate W1 is transferred to the bonding apparatus 41 of the second processing block G2 by the transfer device 61. The first substrate W1 carried into the bonding apparatus 41 is then transferred into the position adjusting mechanism via the transition, and the direction of the first substrate W1 in the horizontal direction is adjusted by the position adjusting mechanism (process S103).

Thereafter, the first substrate W1 is delivered to the inverting mechanism from the position adjusting mechanism, and the front surface and the rear surface of the first substrate W1 are inverted by the inverting mechanism (process S104). To elaborate, the bonding surface W1j of the first substrate W1 is turned to face down. Then, the first substrate W1 is delivered to the first holder 110 from the inverting mechanism, and attracted to and held by the first holder 110 (process S105).

In parallel with the processing of the processes S101 to S105 upon the first substrate W1, a processing of the second substrate W2 is performed. First, the second substrate W2 is taken out of the cassette C2 by the transfer device 22, and transferred to the transition disposed in the third processing block G3.

Then, the second substrate W2 is transferred to the surface modifying apparatus 30 by the transfer device 61, and the bonding surface W2j of the second substrate W2 is modified (process S106). Thereafter, the second substrate W2 is transferred to the surface hydrophilizing apparatus 40 by the transfer device 61, and the bonding surface W2j of the second substrate W2 is hydrophilized and cleaned (process S107).

Subsequently, the second substrate W2 is transferred to the bonding apparatus 41 by the transfer device 61. The second substrate W2 carried into the bonding apparatus 41 is transferred to the position adjusting mechanism via the transition. Then, the direction of the second substrate W2 in the horizontal direction is adjusted by the position adjusting mechanism (process S108).

Afterwards, the second substrate W2 is transferred to above the second holder 120, and the elevating device 170 of the second holder 120 receives the second substrate W2. Then, the ionizer 160 neutralizes the electric charges of the second substrate W2 carried to and held by the second holder 120 (process S109). At this time, the ionizer 160 may neutralize the second holder 120.

Afterwards, the second substrate W2 is transferred to the second holder 120 and attracted to and held by the second holder 120 with a notch thereof directed toward a predetermined direction (process S110).

Next, the position adjustment between the first substrate W1 held by the first holder 110 and the second substrate W2 held by the second holder 120 in the horizontal direction is performed (process S111). Specifically, the second substrate W2 is moved by using the first moving device 131 and the second moving device 132 so that a center position of the second substrate W2 coincides with a center position of the first substrate W1.

Subsequently, the first substrate W1 and the second substrate W2 are bonded (process S112).

First, the positions of the first substrate W1 held by the first holder 110 and the second substrate W2 held by the second holder 120 in the vertical direction are adjusted. Specifically, the second moving device 132 moves the second holder 120 vertically upwards, thus allowing the second substrate W2 to be brought closer to the first substrate W1.

Next, after releasing the attracting and holding of the first substrate W1 by the plurality of inner attraction portions 116, the push pin 181 of the striker 180 is lowered to press down the central portion of the first substrate W1.

If the central portion of the first substrate W1 comes into contact with the central portion of the second substrate W2 and the central portions of the first and second substrates W1 and W2 are pressed by the striker 180 with a preset force, bonding is started between the pressed central portions of the first and second substrates W1 and W2. That is, since the bonding surface W1j of the first substrate W1 and the bonding surface W2j of the second substrate W2 are modified, a van der Waals force (intermolecular force) is first generated between the bonding surfaces W1j and W2j, so that the bonding surfaces W1j and W2j are bonded to each other. Furthermore, since the bonding surface W1j of the first substrate W1 and the bonding surface W2j of the second substrate W2 are hydrophilized, hydrophilic groups between the bonding surfaces W1j and W2j are hydrogen-bonded, so that the bonding surfaces W1j and W2j are strongly bonded. In this way, a bonding region is formed.

Thereafter, a bonding wave whereby the bonding region gest expanded from the central portions of the first and second substrates W1 and W2 toward the peripheral portions thereof occurs between the first substrate W1 and the second substrate W2. Afterwards, the attracting and holding of the first substrate W1 by the plurality of outer attraction portions 115 is released. Accordingly, the peripheral portion of the first substrate W1 attracted to and held by the outer attraction portions 115 falls down. As a result, the entire bonding surface W1j of the first substrate W1 and the entire bonding surface W2j of the second substrate W2 are brought into contact with each other to thereby form the combined substrate T.

Afterwards, the push pin 181 is raised to the first holder 110 to release the attracting and holding of the second substrate W2 by the second holder 120. Then, the ionizer 160 neutralizes the electric charges of the second holder 120 when the combined substrate T is separated from the holding surface 125 to be carried out (process S113). Thereafter, the combined substrate T is carried out from the bonding apparatus 41 by the transfer device 61. In this way, the series of processes of the bonding processing is completed.

Additionally, although the ionizer 160 is always kept on to emit the ions, the present disclosure is not limited thereto. As an example, the ionizer 160 may be turned on to emit the ions when the second holder 120 is placed at the carry-in/out position, whereas it may be turned off when the second holder 120 is located at the bonding position. In this way, the on/off control of the ionizer 160 may be performed at any required timing.

As described above, the bonding apparatus 41 according to the first exemplary embodiment includes the first holder 110, the second holder 120, the striker 180, and the ionizer 160. The first holder 110 attracts and holds the first substrate W1 from above. The second holder 120 is disposed below the first holder 110, and serves to attract and hold the second substrate W2 from below. The striker 180 presses the central portion of the first substrate W1 into contact with the second substrate W2. The ionizer 160 is disposed above the second holder 120.

Therefore, according to the bonding apparatus 41 of the first exemplary embodiment, it becomes possible to neutralize the electric charges of the second substrate W2 and the second holder 120, so that the bonding defect may be suppressed when the substrates are bonded to each other.

Furthermore, the bonding apparatus 41 is equipped with the moving device 130. The moving device 130 moves the second holder 120 between the carry-in/out position where the carry-in of the second substrate W2 and the carry-out of the combined substrate T, in which the first substrate W1 and the second substrate W2 are bonded to each other, are performed and the facing position where the second holder 120 faces the first holder 110. Additionally, the ionizer 160 is disposed above the second holder 120 located at the carry-in/out position. Thus, the electric charges of the second holder 120 placed at the carry-in/out position and the electric charges of the second substrate W2 held by the second holder 120 can be neutralized.

In addition, the ionizer 160 neutralizes the electric charges of the second substrate W2 carried to and held by the second holder 120. Further, the ionizer 160 neutralizes the electric charges of the second holder 120 where the combined substrate T in which the first substrate W1 and the second substrate W2 are bonded to each other is separated from the holding surface 125. In detail, the ionizer 160 first neutralizes the electric charges of the second substrate W2 carried to and held by the second holder 120, and then neutralizes the electric charges of the second holder 120 where the combined substrate T is separated from the holding surface 125. As a result, it becomes possible to effectively neutralize the electric charges of the second substrate W2 and the second holder 120, so that the bonding defect that may occur when the substrates are bonded to each other can be further suppressed.

Furthermore, the bonding apparatus 41 includes the housing 100 that accommodates at least the second holder 120 therein. The ionizer 160 includes the head 162 disposed inside the housing 100 and configured to emit the ions, and the power supply 161 disposed outside the housing 100 and connected to the head 162. With this configuration, the ionizer 160 is capable of neutralizing the electric charges of the second holder 120 and the like within the housing 100 with the ions from the head 162. Also, the ionizer 160 is capable of reducing the influence of the heat generated by the power supply 161 on the internal space of the housing 100.

In addition, the bonding apparatus 41 is equipped with the gas supply 140 configured to supply the gas to the inside of the housing 100. The ionizer 160 is disposed on the upstream side of the gas flow with respect to the center position C of the second holder 120. With this configuration, the ionizer 160 can cause the emitted ions to reach a wide range of the second substrate W2 or second holder 120 along the gas flow, thus allowing the second substrate W2 and the second holder 120 to be efficiently neutralized.

### Second Exemplary Embodiment

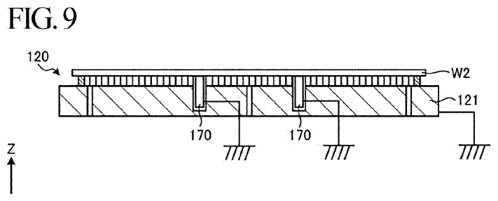

The above first exemplary embodiment has been described for the example of neutralizing the charged second substrate W2 and second holder 120 by using the ionizer 160. Without being limited thereto, the bonding apparatus 41 may be configured to neutralize the electric charges of the second substrate W2 and the second holder 120 while suppressing the charging of the second substrate W2 and the second holder 120. FIG. 9 is a schematic diagram showing a configuration example of the second holder 120 of the bonding apparatus 41 according to a second exemplary embodiment. The bonding apparatus 41 according to the second exemplary embodiment is not provided with the ionizer 160.

As shown in FIG. 9, the second holder 120 according to the second exemplary embodiment is grounded. Further, the second holder 120 is formed of a conductive member. The conductive member may be a metal material (e.g., aluminum) or conductive ceramic (e.g., silicon carbide), but not limited thereto.

As stated above, the second holder 120 according to the second exemplary embodiment is formed of the conductive member and is grounded. Thus, even when the second substrate W2 is carried to and held on the second holder 120 in the charged state or even when the non-illustrated combined substrate T is separated from the second holder 120, static electricity and the like can be eliminated. Therefore, it becomes possible to perform the charge neutralization while suppressing the charging.

Therefore, when bonding the first substrate W1 and the second substrate W2 in the current processing or the next processing, for example, the difference in charged amount between the first substrate W1 and the second substrate W2 becomes relatively small, so that the electric discharge can be suppressed. As a result, the formation of the void between the first substrate W1 and the second substrate W2, which is caused by the electric discharge, can be suppressed, so that the bonding defect that may occur when the substrates are bonded to each other can be suppressed.

Moreover, the elevating device 70 of the second holder 120 according to the second exemplary embodiment is grounded. The elevating device 170 is formed of a conductive member. The conductive member may be a metal material (e.g., aluminum) or conductive ceramic (e.g., silicon carbide), but is not limited thereto.

As stated above, the elevating device 170 according to the second exemplary embodiment is formed of the conductive member and is grounded. Thus, even when the second substrate W2 is carried to and received by the elevating device 170 or even when the elevating device 170 raises the non-illustrated combined substrate T to separate it, static electricity and the like can be eliminated. Therefore, it becomes possible to perform the charge neutralization while suppressing the charging. As a result, the bonding defect that may occur when the substrates are bonded to each other can be suppressed, as stated above.

### <Specific Operation of Bonding System>

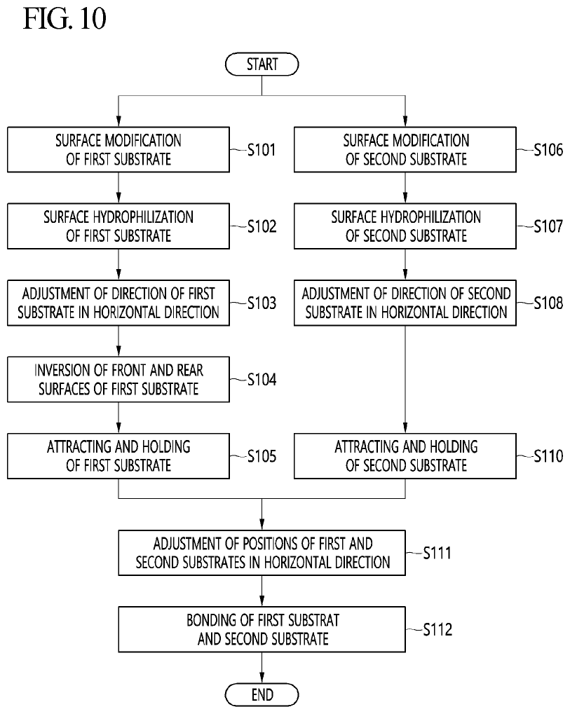

Now, a specific operation of the bonding system 1 according to the second exemplary embodiment will be described with reference to FIG. 10. FIG. 10 is a flowchart showing a sequence of a processing performed by the bonding system 1 according to the second exemplary embodiment. Various processes shown in FIG. 10 are performed under the control of the control device 70.

As illustrated in FIG. 10, in the processing performed by the bonding system 1 according to the second exemplary embodiment, the process using the ionizer 160 as in the first exemplary embodiment is omitted. In detail, the process S109 of neutralizing the electric charges of the second substrate W2 and the like by using the ionizer 160 and the process S113 of neutralizing the electric charges of the second holder 120 by using the ionizer 160 are omitted.

Although the processes S109 and S113 are omitted, the second substrate W2 and the second holder 120 are neutralized while their charging is suppressed by the second holder 120 and the elevating device 170 configured as described above.

In addition, the above-described first and second exemplary embodiments may be appropriately combined. That is, by combining the first and second exemplary embodiments, the second holder 120 or the like may be formed of a conductive member and grounded in the bonding apparatus 41 equipped with the ionizer 160.

Further, the present disclosure may also adopt the following configuration.

(1)

A bonding apparatus, including:
a first holder configured to attract and hold a first substrate from above;
a second holder, disposed below the first holder, configured to attract and hold a second substrate from below;
a striker configured to press a central portion of the first substrate into contact with the second substrate; and
an ionizer disposed above the second holder.
   (2)

The bonding apparatus described in (1), further including:
a moving device configured to move the second holder between a carry-in/out position where a carry-in of the second substrate and a carry-out of a combined substrate, in which the first substrate and the second substrate are bonded to each other, are performed and a facing position where the second holder faces the first holder,
wherein the ionizer is disposed above the second holder located at the carry-in/out position.
   (3)

The bonding apparatus described in (1) or (2),
wherein the ionizer is configured to neutralize electric charges of the second substrate carried to and held by the second holder.
   (4)

The bonding apparatus described in any one of (1) to (3),
wherein the ionizer is configured to neutralize electric charges of the second holder where a combined substrate, in which the first substrate and the second substrate are bonded to each other, is separated from a holding surface.
   (5)

The bonding apparatus described in any one of (1) to (4),
wherein the ionizer is configured to neutralize electric charges of the second substrate carried to and held by the second holder and then neutralize electric charges of the second holder where a combined substrate, in which the first substrate and the second substrate are bonded to each other, is separated from a holding surface.
   (6)

The bonding apparatus described in any one of (1) to (5), further including:
a housing accommodating at least the second holder therein,
wherein the ionizer includes:
a head disposed inside the housing, and configured to emit an ion; and
a power supply disposed outside the housing, and connected to the head.
   (7)

The bonding apparatus described in any one of (1) to (6), further including:
a housing accommodating at least the second holder therein; and
a gas supply configured to supply a gas into the housing,
wherein the ionizer is disposed on an upstream side of a flow of the gas with respect to a center position of the second holder.
   (8)

A bonding apparatus, including:
a first holder configured to attract and hold a first substrate from above;
a second holder, disposed below the first holder, configured to attract and hold a second substrate from below; and
a striker configured to press a central portion of the first substrate into contact with the second substrate,
wherein the second holder is formed of a conductive member, and is grounded.
   (9)

The bonding apparatus described in (8),
wherein the second holder includes an elevating device configured to perform a descending operation to lower the second substrate carried thereto to a holding surface and an ascending operation to raise a combined substrate, in which the first substrate and the second substrate are bonded to each other, up to a carry-out position from the holding surface, and
the elevating device is formed of a conductive member, and is grounded.
   (10)

A bonding system, including:
a surface modifying apparatus configured to modify surfaces of a first substrate and a second substrate;
a surface hydrophilizing apparatus configured to hydrophilize the modified surfaces of the first substrate and the second substrate; and
a bonding apparatus configured to bond the hydrophilized first and second substrates by an intermolecular force,
wherein the bonding apparatus includes:
a first holder configured to attract and hold the first substrate from above;
a second holder, disposed below the first holder, configured to attract and hold the second substrate from below;
a striker configured to press a central portion of the first substrate into contact with the second substrate; and
an ionizer disposed above the second holder.
   (11)

A bonding system, including:
a surface modifying apparatus configured to modify surfaces of a first substrate and a second substrate;
a surface hydrophilizing apparatus configured to hydrophilize the modified surfaces of the first substrate and the second substrate; and
a bonding apparatus configured to bond the hydrophilized first and second substrates by an intermolecular force,
wherein the bonding apparatus includes:
a first holder configured to attract and hold the first substrate from above;
a second holder, disposed below the first holder, configured to attract and hold the second substrate from below; and
a striker configured to press a central portion of the first substrate into contact with the second substrate, and
wherein the second holder is formed of a conductive member and is grounded.
   (12)

A bonding method, including:
neutralizing, by using an ionizer, electric charges of a second holder disposed below a first holder;
attracting and holding a first substrate from above by using the first holder;
neutralizing, by using the ionizer, electric charges of a second substrate carried to and held by the second holder;
attracting and holding the second substrate from below by using the second holder; and
pressing a central portion of the first substrate into contact with the second substrate by using the striker.
   (13) A bonding method, including:
attracting and holding a first substrate from above by using a first holder;
attracting and holding a second substrate from below by using a second holder; and
pressing a central portion of the first substrate into contact with the second substrate by using a striker,
wherein the second holder is formed of a conductive member and is grounded.

According to the exemplary embodiment, it is possible to suppress the bonding defect that may occur when the substrates are bonded to each other.

It should be noted that the above-described exemplary embodiments are illustrative in all aspects and are not anyway limiting. In fact, the above-described exemplary embodiments can be embodied in various forms. Further, the above-described exemplary embodiments may be omitted, replaced and modified in various ways without departing from the scope and the spirit of claims.

We claim:

1. A bonding apparatus, comprising:
a first holder configured to attract and hold a first substrate from above;
a second holder, disposed below the first holder, configured to attract and hold a second substrate from below;
a striker configured to press a central portion of the first substrate into contact with the second substrate; and
an ionizer disposed above the second holder.

2. The bonding apparatus of claim 1, further comprising:
a moving device configured to move the second holder between a carry-in/out position where a carry-in of the second substrate and a carry-out of a combined substrate, in which the first substrate and the second substrate are bonded to each other, are performed and a facing position where the second holder faces the first holder,
wherein the ionizer is disposed above the second holder located at the carry-in/out position.

3. The bonding apparatus of claim 1,
wherein the ionizer is configured to neutralize electric charges of the second substrate carried to and held by the second holder.

4. The bonding apparatus of claim 1,
wherein the ionizer is configured to neutralize electric charges of the second holder where a combined substrate, in which the first substrate and the second substrate are bonded to each other, is separated from a holding surface.

5. The bonding apparatus of claim 1,
wherein the ionizer is configured to neutralize electric charges of the second substrate carried to and held by the second holder and then neutralize electric charges of the second holder where a combined substrate, in which the first substrate and the second substrate are bonded to each other, is separated from a holding surface.

6. The bonding apparatus of claim 1, further comprising:
a housing accommodating at least the second holder therein,
wherein the ionizer comprises:
a head disposed inside the housing, and configured to emit an ion; and
a power supply disposed outside the housing, and connected to the head.

7. The bonding apparatus of claim 1, further comprising:
a housing accommodating at least the second holder therein; and
a gas supply configured to supply a gas into the housing,
wherein the ionizer is disposed on an upstream side of a flow of the gas with respect to a center position of the second holder.

8. A bonding system, comprising:
a surface modifying apparatus configured to modify surfaces of a first substrate and a second substrate;
a surface hydrophilizing apparatus configured to hydrophilize the modified surfaces of the first substrate and the second substrate; and
a bonding apparatus configured to bond the hydrophilized first and second substrates by an intermolecular force,
wherein the bonding apparatus comprises:
a first holder configured to attract and hold the first substrate from above;
a second holder, disposed below the first holder, configured to attract and hold the second substrate from below;
a striker configured to press a central portion of the first substrate into contact with the second substrate; and
an ionizer disposed above the second holder.
